(19) United States
(12) Patent Application Publication
(10) Pub. No.: US 2023/0317489 A1
(43) Pub. Date: Oct. 5, 2023

(54) ADJUSTABLE CARRYING DEVICE

(71) Applicant: DLY TECHNOLOGIES INC., Kaohsiung City (TW)

(72) Inventor: SHIH FENG PAN, Pingtung County (TW)

(21) Appl. No.: 18/129,333

(22) Filed: Mar. 31, 2023

(30) Foreign Application Priority Data
Mar. 31, 2022 (TW) 111112649
Jun. 22, 2022 (TW) 111123279
Dec. 27, 2022 (TW) 111150196

(51) Int. Cl. H01L 21/677

(52) U.S. Cl. CPC H01L 21/67769; H01L 21/67766

(57) ABSTRACT

The invention comprises an adjustable carrying device comprises at least two first containing plates, at least two second containing plates that arranged interval with the first containing plates, and a plurality of stretchable elements that are arranged on the containing plates, each of the first containing plates comprises at least one first upper positioning member, at least one first lower positioning member, a first holding element, and a bracing member for abutting against a substrate, each of the second containing plates comprises at least one second upper positioning member, at least one second lower positioning member, a second holding element, and a bracing member for abutting against a substrate, the stretchable elements can shrink to effectively reduce the overall volume of the adjustable carrying device, the edge of the substrates can be positioned by these positioning member to avoid the failure of placement, the holding elements can prevent the containing plates from slipping off or colliding with the inner wall of the containing plate to cause damage, a part of the bracing element can abut against the bottom surface of the substrate, to counteract or slow down the deformation and depression of the substrate due to the influence of gravity.

### CROSS-REFERENCE TO RELATED APPLICATION

This application claims the priority benefit of Taiwan application No. 111112649, filed 2022 Mar. 31, and Taiwan application No. 111123279, filed 2022 Jun. 22, and Taiwan application No. 111150196, filed 2022 Dec. 27. The entirety of each of the above-mentioned patent applications is hereby incorporated by reference herein and made a part of this specification.

### TECHNICAL FIELD

This application is related to a carrier device, especially for an adjustable carrying device with volume reduction characteristics.

### BACKGROUND

The conventional wafer box mainly adopts a stacking method to store a plurality of wafers or display substrates. However, it would be a fixed distance between the stored wafers, for example, the distance between the containing plate in the wafer box is about 10 mm, so the wafer box has a certain volume which occupies quite a lot of work space. In addition, each containing plate has a carrying portion for placing wafers, and a hollow portion surrounded by the carrying portion for a robot arm to access wafers. In order to prevent the robotic arm from accidentally dropping a part of the edge of the wafer into the hollow part due to the position error while storing the wafer, which will cause the wafer to tilt and failed of placement, therefore, the conventional carrying portion of containing plate increases its area toward the hollow portion as much as possible, so that the weight of each containing plate and even the entire wafer box increases significantly, which not only increases the production cost, but also hinder the efficiency of transportation of wafer box. On the other hand, as the area of the wafer increases and becomes thinner, if the conventional wafer box is placed horizontally when carrying a large wafer, for example, in the manufacturing preparation stage, it is easy to cause deformation and depression of the thinner wafer which has a large span due to the influence of gravity. In this case, the wafer is likely to be shaken and damaged during the transportation process, so additional equipment is required to stabilize the wafer, thus greatly increasing production costs.

### SUMMARY

Therefore, one purpose of the invention is to provide an adjustable carrying device with stretchable function that can effectively reduce the volume, and the edge of the wafer could be positioned by the positioning members to avoid positioning error, so it would not easy to be displaced and dropped while processing placement of wafer. And the wafers can be resisted and supported during the transportation process, it will not easily slip or collide to cause damage.

For the aforementioned purpose, the invention disclose an adjustable carrying device for containing a plurality of substrates, comprising: at least two first containing plates, at least two second containing plates, and a plurality of stretchable elements; Each first containing plate can respectively carry a first substrate, and has a first top surface, a first bottom surface, at least one first upper positioning member protruding upward from the first top surface, at least one first lower positioning member protruding downward from the first bottom surface, a first holding element for resisting substrate, and a bracing element. The first holding element comprising a first holding side wall, a first embedding opening, and a first bump, and when the first substrate is placed on the containing plate, a part of the bracing element abut against the bottom surface of the first substrate; Each second containing plate can respectively carry a second substrate, the second containing plates are arranged interval with the first containing plates, and has a second top surface, a second bottom surface, at least one second upper positioning member protruding upward from the second top surface, at least one second lower positioning member protruding downward from the second bottom surface, a second holding element for resisting substrate, and a bracing element. The second holding element comprising a second holding side wall, a second embedding opening, and a second bump, and when the second substrate is placed on the containing plate, a part of the bracing element is attached to the bottom surface of the second substrate; The plurality of stretchable elements are arranged on the first containing plate and the second containing plate, so that the distance between the first containing plate and the second containing plate could be increased to form an extension state, or decreased to form a compression state. Wherein, when the plurality of stretchable elements are stretched to decrease the distances between the containing plates, the first holding element can resist the second substrate carried by the second containing plate, and the second resisting element can resist a first substrate carried by the other adjacent first containing plate.

For the aforementioned purpose, the disclosure provides a carrying device for containing a plurality of substrates, comprising at least two first containing plates, at least two second containing plates, and a plurality of stretchable elements. Each first containing plate can respectively carry a first substrate, comprising at least one protruding member and at least one first fasten member, each second containing plate can respectively carry a second substrate, comprising at least one protruding member and at least one second fasten member. The plurality of stretchable elements are arranged on the first containing plate and the second containing plate, so that the distance between the first containing plate and the second containing plate could be increased to form an extension state, or decreased to form a compression state. When the containing plates are in a compression state, one protruding member and the other protruding member on the adjacent containing plate are joined together, and the first fasten members is inserted into the second fasten member, the fasten members are mutually connected.

Therefore, the plurality of stretchable elements could expand the distance between containing plates for the robotic arm to pick and place the substrates, or to shrink to decrease the overall volume of the adjustable carrying device and to streamline the working space. While placing the substrates on the containing plates, the edge of the substrate could be positioned by the positioning members to avoid the displacement and drop which will cause the substrate to tilt and failed of placement. On the other hand, the holding elements could prevent the containing plates from slipping off or colliding with the inner wall of the containing plate to cause damage, when the protruding members are covered by each other, and the fasten members are fixedly engaged with each other, it can effectively prevent the containing plates from being misaligned due to the shaking during the transportation process, which will cause damage as a result of the movement and collision of the substrates.

### BRIEF DESCRIPTION OF THE DRAWINGS

FIG. 1 is a stereograph of an adjustable carrying device according to the preferred embodiment of the present invention.

FIG. 2 is a schematic view of a partial enlargement of the adjustable carrying device according to the preferred embodiment of the present invention.

FIG. 3 is a stereograph of a first containing plate of the adjustable carrying device according to the preferred embodiment of the present invention.

FIG. 4 is a stereograph of a second containing plate of a adjustable carrying device according to the preferred embodiment of the present invention.

FIG. 5 is a partial side view of an adjustable carrying device according to the preferred embodiment of the present invention.

FIG. 6 is a partial side view of an adjustable carrying device according to another embodiment of the present invention.

FIG. 7 and FIG. 8 are stereograph of enlargement of a holding element of the adjustable carrying device according to the preferred embodiment of the present invention.

FIG. 9 and FIG. 10 are operational views of a holding element of one of the containing plates, to be embedded into the holding element of the next containing plate according to the preferred embodiment of the present invention.

FIG. 11 is a schematic view of a locating member of the adjustable carrying device according to the preferred embodiment of the present invention.

FIG. 12 is a partial stereograph showing first containing plate and bracing element according to the preferred embodiment of the present invention.

FIG. 13 is a partial stereograph showing a first containing plate according to the preferred embodiment of the present invention.

FIG. 14 is a stereograph showing a bracing element in contact with a substrate according to one of the preferred embodiments of the present invention.

FIG. 15 is a side view of the embodiment of FIG. 14

FIG. 16 is a partial side sectional view of a substrate of the present invention placed on the containing plate of the embodiment of FIG. 12

### DETAILED DESCRIPTION

Reference will now be made in detail to the exemplary embodiments of the disclosure, examples of which are illustrated in the accompanying drawings. Wherever possible, the same reference numbers are used in the drawings and the description to refer to the same or like parts.

Some words are used to refer to specific elements in the whole specification and the appended claims in the disclosure. A person skilled in the art should understand that a substrate carrying device manufacturer may use different names to refer to the same elements. The specification is not intended to distinguish elements that have the same functions but different names. In the following specification and claims, the terms “having”, “including”, etc. are open-ended terms, so they should be interpreted to mean “including but not limited to . . . ”.

It should be noted that in the following embodiments, features in a plurality of embodiments may be replaced, recombined, or mixed to complete other embodiments without departing from the spirit of the disclosure. The features of the embodiments may be used in any combination without departing from the spirit of the disclosure or conflicting with each other.

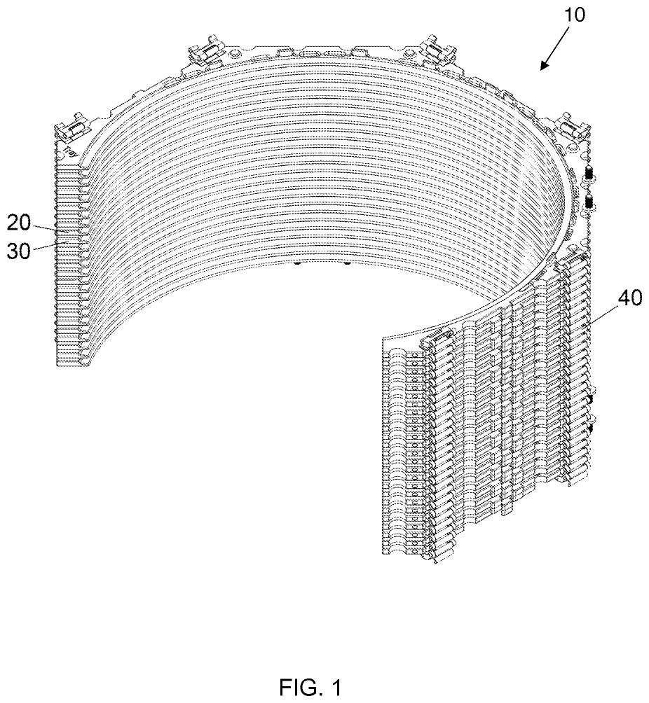

The technical content and feature of the invention is illustrated by the following embodiment and figures. Referring to FIG. 1, an adjustable carrying device 10 according to the first embodiment of the disclosure for containing a plurality of substrates, comprising at least two first containing plates 20, at least two second containing plates 30, and a plurality of stretchable elements 40. In this embodiment, both the first containing plate 20 and the second containing plate 30 can carry a substrate respectively, and the total number of the first containing plate 20 and the second containing plate 30 is 25, but it is not limited to this.

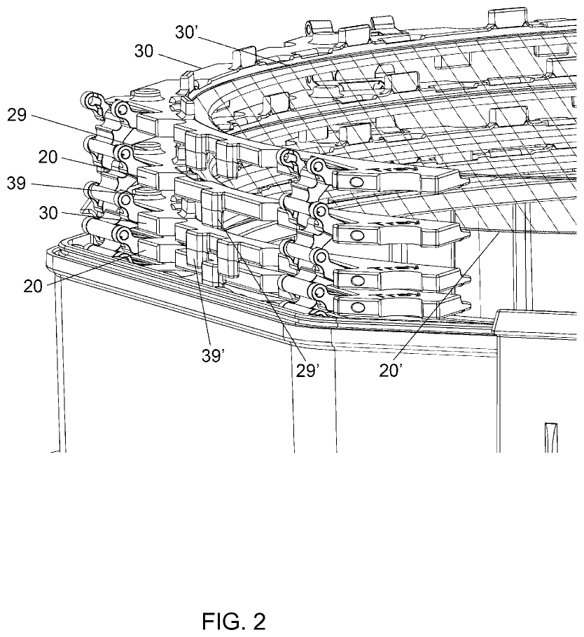

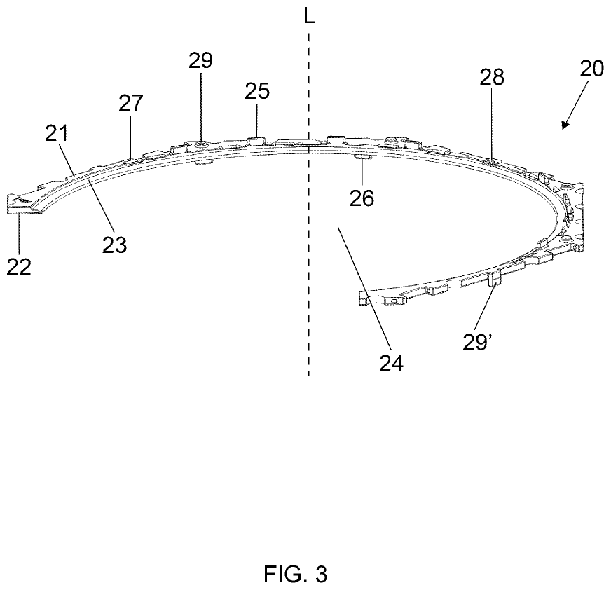

Referring to FIG. 2, the first containing plates 20 are arranged interval with the second containing plates 30, and the first containing plate 20 can respectively carry a first substrate 20′, the second containing plate 30 can respectively carry a second substrate 30′. Referring to FIG. 3, each first containing plate 20 has a first top surface 21, a first bottom surface 22. A first carrying portion 23 extends obliquely from the first top surface 21 toward an imaginary central line L, for the first substrate 20′ to lean against, a first hollow portion 24 is surrounded by the first carrying portion 23 for a robotic arm (not shown) to access the first substrate 20′. A plurality of first upper positioning members 25 protrude upward from the first top surface 21 and surround the first carrying portion 23, a plurality of first lower positioning members 26 protrude downward from the first bottom surface 22 and surround the first carrying portion 23, a plurality of first accommodating holes 27 passes through both the first top surface 21 and the first bottom surface 22 and surround the first carrying portion 23, a first holding element 28 is disposed on the periphery of the first carrying portion 23 for resisting the second substrate 30′ carried by the second containing plate 30, a plurality of protruding members 29 protrude upward from the first top surface 21, and a plurality of first fasten members 29′ protrude downward from the side of the first containing plate 20. The first containing plate 20 can be made by one-piece injection molding, and its material can be plastic PVC. According to the embodiment, the number of the first holding element 28 could be multiple, and are arranged in an arc type around the first containing plate 20. The protruding member 29 is made into a cover shape, and the first fasten member 29′ is made into a block shape. In another embodiment, the number of the first upper positioning member 25 and the first lower positioning member 26 could be changed according to requirements, but there must be at least one.

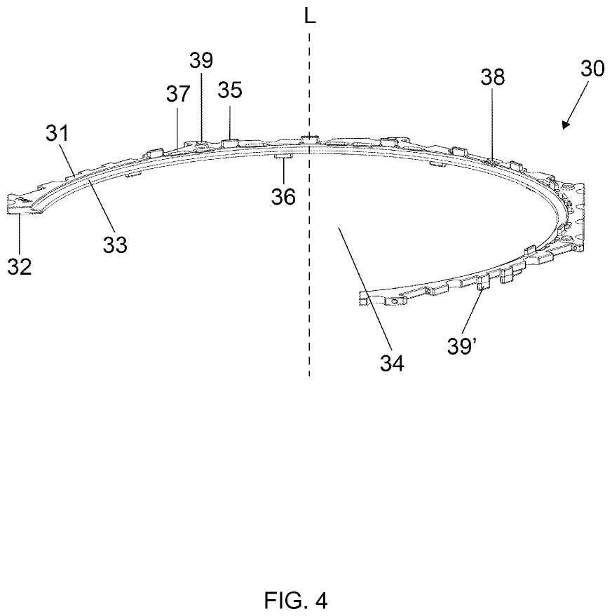

Referring to FIG. 4, each second containing plate 30 has a second top surface 31, a second bottom surface 32. A second carrying portion 33 extends obliquely from the second top surface 31 toward an imaginary central line L, for the second substrate 30′ to lean against, a second hollow portion 34 is surrounded by the second carrying portion 33 for a robotic arm (not shown) to access the second substrate 30′. A plurality of second upper positioning members 35 protrude upward from the second top surface 31 and surround the second carrying portion 33, a plurality of second lower positioning members 36 protrude downward from the second bottom surface 32 and surround the second carrying portion 33, a plurality of second accommodating holes 37 passes through both the second top surface 31 and the second bottom surface 32 and surround the second carrying portion 33, a second holding element 38 is disposed on the periphery of the second carrying portion 33 for resisting the first substrate 20′ carried by the first containing plate 20, a plurality of protruding members 39 protrude upward from the second top surface 31, and a plurality of second fasten members 39′ protrude downward from the side of the second containing plate 30. The second containing plate 30 can be made by one-piece injection molding, and its material can be plastic PVC. According to the embodiment, the number of the second holding element 38 could be multiple, and are arranged in a arc type around the second containing plate 30. The protruding member 39 is made into a cover shape, and the second fasten member 39′ is made into a groove shape. In another embodiment, the number of the second upper positioning member 35 and the second lower positioning member 36 could be changed according to requirements, but there must be at least one.

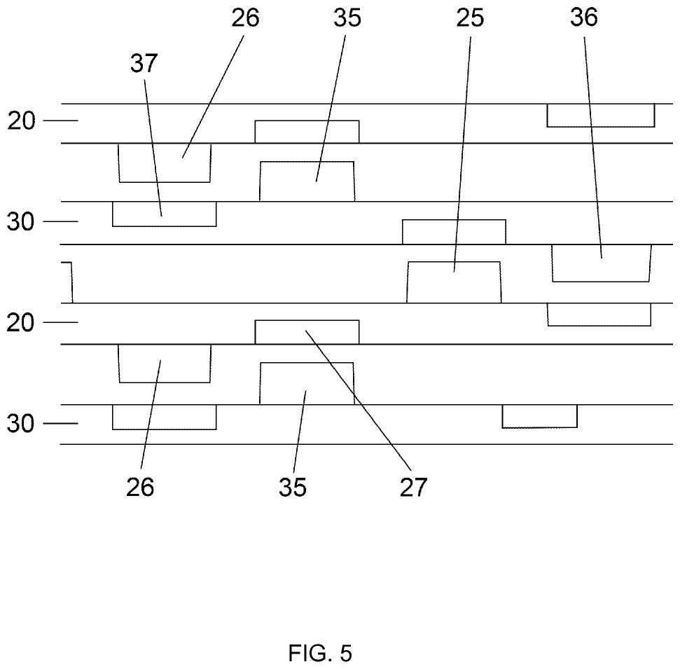

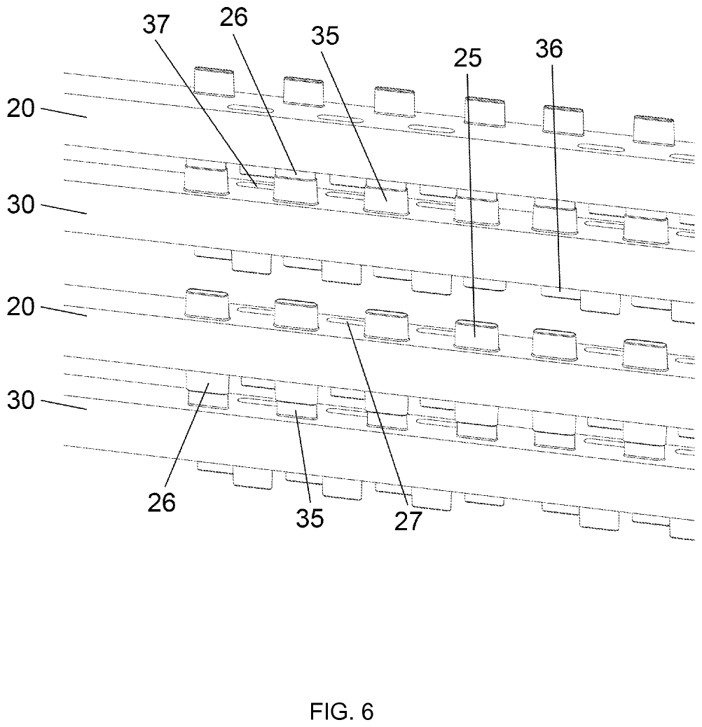

Referring to FIG. 2 to FIG. 5, according to the embodiment, the positions of each of the first lower positioning members 26 and each of the second upper positioning members 35 do not overlap each other in the vertical direction and the horizontal direction, the positions of each of the first upper positioning members 25 and each of the second lower positioning members 36 do not overlap each other in the vertical direction and the horizontal direction. Each of the first upper positioning member 25, each of the first lower positioning member 26, and each of the first accommodating holes 27 is equivalent to the distance from the imaginary center line L. Each of the second upper positioning member 35, each of the second lower positioning member 36, and each of the second accommodating holes 37 is equivalent to the distance from the imaginary center line L, however, in other embodiment, it is not limited to the above mentioned, for example, the distance between the first lower positioning members 26 and the imaginary center line L may be greater than the distance between the second upper positioning members 35 and the imaginary center line L, in such situation, if viewed from the perspective of FIG. 5, the positions of the first lower positioning members 26 and the second upper positioning members 35 may overlap each other in the horizontal direction. Even, referring to FIG. 6, the second upper positioning members 35 can be further provided with a notch for the first lower positioning members 26 to extend into. In this case, the second accommodating hole 37 of the second containing plate 30 could be omitted, that is to say, the second accommodating hole 37 could instead be recessed in the second upper positioning member 35, so that the positions of the first lower positioning members 26 and the second upper positioning members 35 in the vertical direction will be overlap each other. Similarly, the first lower positioning member 26 can be recessed with a notch for the second upper positioning members 35 to extend into. In this case, the second accommodating hole 37 of the second containing plate 30 can also be omitted. The first accommodating hole 27 could also be recessed in the first upper positioning member 25 or the second lower positioning member 36, as long as they can be butted with each other.

The plurality of stretchable elements 40 are arranged on the first containing plate 20 and the second containing plate 30, so that the distance between the first containing plate 20 and the second containing plate 30 could be increased to form an extension state, or decreased to form a compression state, when the first containing plate 20 and the second containing plate 30 are in the compression state, each of the first lower positioning members 26 can extend into the second accommodating holes 37 located below the corresponding position, and the first upper positioning member 25 can extend into the second accommodating hole 37 located above the corresponding position. Furthermore, each of the second upper positioning members 35 can extend into the first accommodating holes 27 located above the corresponding position, and the second lower positioning member 36 can extend into the first accommodating hole 27 located below the corresponding position.

On the other hand, as shown in FIG. 5, when the first containing plate 20 and the second containing plate 30 are in the extension state, the horizontal position of the bottom edge of each of the first lower positioning members 26 is lower than the horizontal position of the top edge of each of the second upper positioning members 35, and the horizontal position of the top edge of each of the first upper positioning members 25 is higher than the horizontal position of the bottom edge of the second lower positioning member 36. However, in other possible embodiments, the horizontal position of the bottom edge of each of the first lower positioning members 26 can be aligned with the horizontal position of the top edge of each of the second upper positioning members 35, but the horizontal position of the bottom edge of each of the first lower positioning part 26 cannot be higher than the horizontal position of the top edge of each said second upper positioning part 35. Likewise, the horizontal position of the top edge of each of the first upper positioning members 25 can be aligned with the horizontal position of the bottom edge of the second lower positioning member 36, but the horizontal position of the top edge of each of the first upper positioning members 25 cannot be lower than the horizontal position of the bottom edge of the second lower positioning member 36. In this way, the substrates will not penetrate a gap between these upper and lower positioning members when placed, for the avoidance of causing positioning failure.

With the above-mentioned structure, the plurality of stretchable elements 40 could expand the distance between each first containing plates 20 and each second containing plates 30 for the robotic arm to pick and place the substrates, or to shrink to decrease the overall volume of the adjustable carrying device and to streamline the working space. In addition, when the first containing plates 20 and the second containing plates 30 are in the extension state, the robotic arm could place the substrate on the containing plate 20 or the second containing plate 30, the edge of the substrate could be positioned by these first upper positioning member 25, first lower positioning member 26, second upper positioning member 35, and second lower positioning member 36, to avoid the accidentally falling into the first hollow portion 24 or the second hollow portion 34 due to the error of the storage position, which will cause the substrate to tilt and failed of placement. Therefore, the area of the first carrying portion 23 and the second carrying portion 33 could be reduced as much as possible during manufacturing, that is, the range of the first hollow portion 24 and the second hollow portion 34 can be expanded, so that the weight of each of the first containing plate 20, each of the second containing plate 30, and even the entire adjustable carrying device 10 could be greatly reduced, which not only reduces the production cost, but also is beneficial to the delivery performance of the adjustable carrying device 10.

When the stretchable elements 40 are in a compression state, the distance between the containing plates are reduced, the first holding element 28 can push the second holding side wall 383 to resist the second substrates 30′ located below, the second holding element 38 can push the first holding side wall 283 to resist the first substrates 20′ located below. In addition, each of the protruding member 29 covers on another protruding member 39 disposed below, and each of the first fastening member 29′ extends into the second fastening member 39′ disposed below. In more detail, the cover-shaped protruding member 29 covers on the protruding member 39, and the block-shaped first fastening member 29′ extends into the groove-shaped the second fastening member 39′, to ensure that the stacking between each containing plate 20, 30 is more stable.

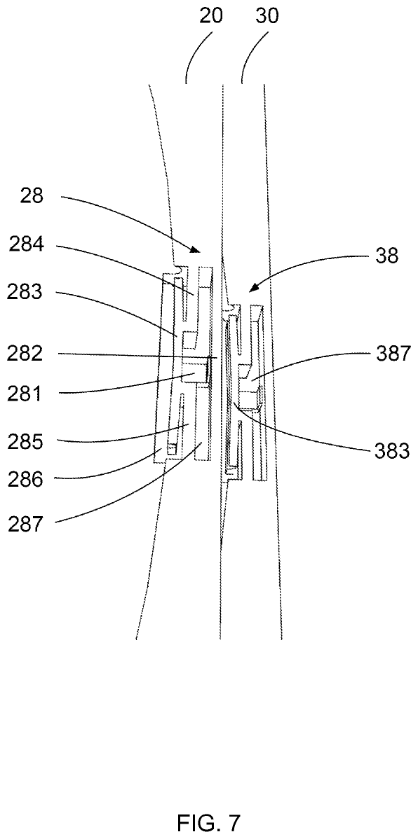

The structure and function of the first holding element 28 and the second holding element 38 will be described below, please refer to FIGS. 7-10. The first holding element 28 comprises a first bump 281, a first fixed side wall 282, a first holding side wall 283, two first connecting portions 284, 285, a first holding opening 286, and a first embedding opening 287, wherein the first bump 281 is connected to the first fixed side wall 282, and the first holding side wall 283 is connected to the first containing plate 20 through the first connection portions 284, 285. The first embedding opening 287 is defined between the first holding side wall 283 and the first fixed side wall 282, and first holding opening 286 is defined between the first holding side wall 283 and the first containing plate 20. The first bump 281 could be located at the center of the first fixed side wall 282 and the first holding side wall 283 in the length direction, the two first connecting portions 284, 285 could be parallel to the first fixed side wall 282 and the first holding side wall 283. The first holding side wall 283 comprises an arc-shaped concave surface to face the first substrate 20′, and could be used to resist the first substrate 20′.

Similarly, the second holding element 38 is the same as the first holding element 28, comprises a second bump 381, a second fixed side wall 382, a second holding side wall 383, two second connecting portions 384, 385, a second holding opening 386, and a second embedding opening 387, wherein the second bump 381 is connected to the second fixed side wall 382, and the second holding side wall 383 is connected to the second containing plate 30 through the second connection portions 384, 385. The second embedding opening 387 is defined between the second holding side wall 383 and the second fixed side wall 382, and second holding opening 386 is defined between the second holding side wall 383 and the second containing plate 30. The second bump 381 could be located at the center of the second fixed side wall 382 and the second holding side wall 383 in the length direction, the two second connecting portions 384, 385 could be parallel to the second fixed side wall 382 and the second holding side wall 383. The second holding side wall 383 comprises an arc-shaped concave surface to face the second substrate 30′, and could be used to resist the second substrate 30′.

Referring to FIG. 8, the first bump 281 comprises a bump top surface 281a, a bump side surface 281b, and a bump bottom surface 281c. The bump side surface 281b could be a bevelled surface, an arc surface, a stepped surface or other type of surfaces. The width of the bump top surface 281a in one direction is smaller than the width of the second embedding opening 387 of the second containing plate 30 located below in the same direction, and the width of the bottom surface 281c in the same direction is greater than the width of the second embedding opening 387 of the second containing plate 30 located below in the same direction. The present invention enables the first bump 281 of the first containing plate 20 to be embedded into the second embedding opening 387 of the corresponding second holding element 38 of the second containing plate 30 located below, then to be able to resist the second substrate 30′ carried by the second containing plate 30, so as to prevent it from slipping or colliding with the inner wall of the containing plate to cause damage.

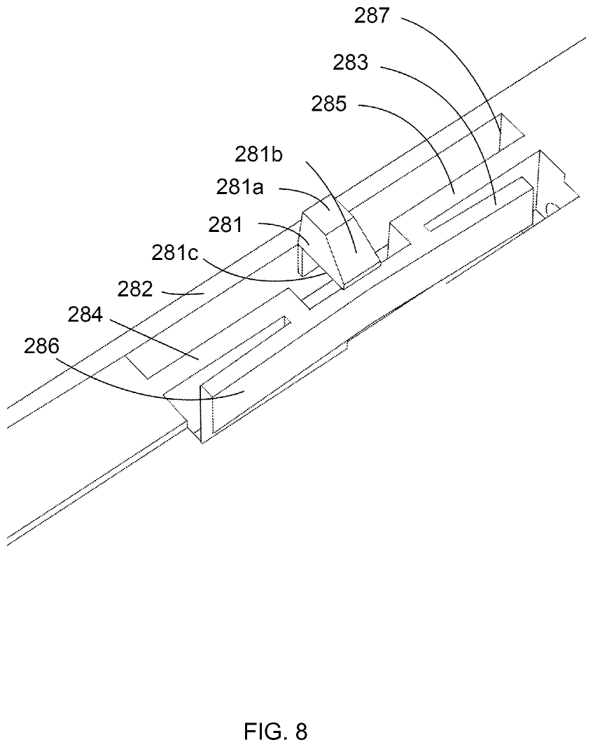

Specifically, as shown in FIG. 9, when the first containing plate 20 and the second containing plate 30 are in an extension state, the second holding side wall 383 is located at its original position, and the second holding opening 386 is sandwiched between the second holding side wall 383 and the second substrate 30′ placed on the second containing plate 30. Referring to FIG. 10, when the first containing plate 20 and the second containing plate 30 are in a compression state, the first bump 281 of the first resisting element 28 of the first containing plate 20 is embedded in the second embedding opening 387 of the second holding element 38 of the second containing plate 30 located below, then the second holding side wall 383 could be pushed to move so that the second holding opening 386 will be reduced, and even the second holding side wall 383 could contact and resist the second substrate 30′.

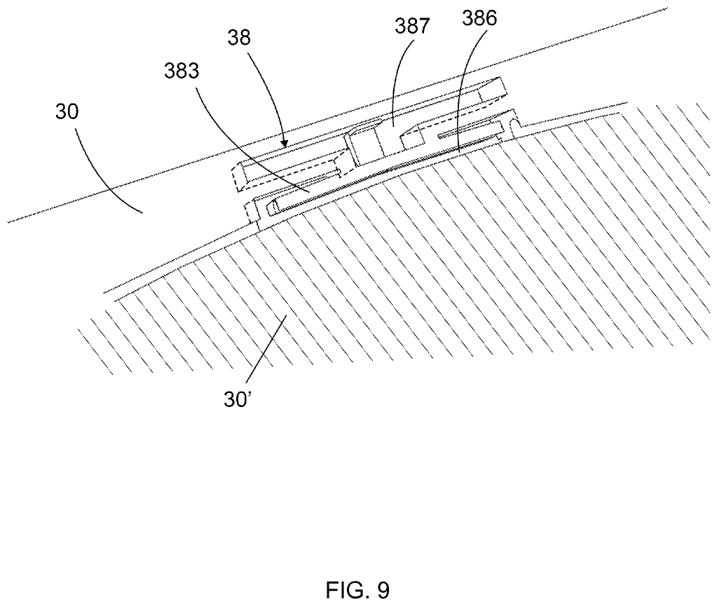

Referring to FIG. 11, The first carrying portion 23 of the first containing plate 20 and the second carrying portion 33 of the second containing plate 30 carry the first substrate 20′ and the second substrate 30′ respectively. The first bottom surface 22 of the first containing plate 20 and the second bottom surface 32 of the second containing plate 30 are further provided with locating members 225 and 325 respectively, when the distance between the containing plate and the adjacent lower containing plate is shortened, the substrate which carried by the lower containing plate will be further positioned by the locating members at a predetermined position of the lower containing plate, such as a central position.

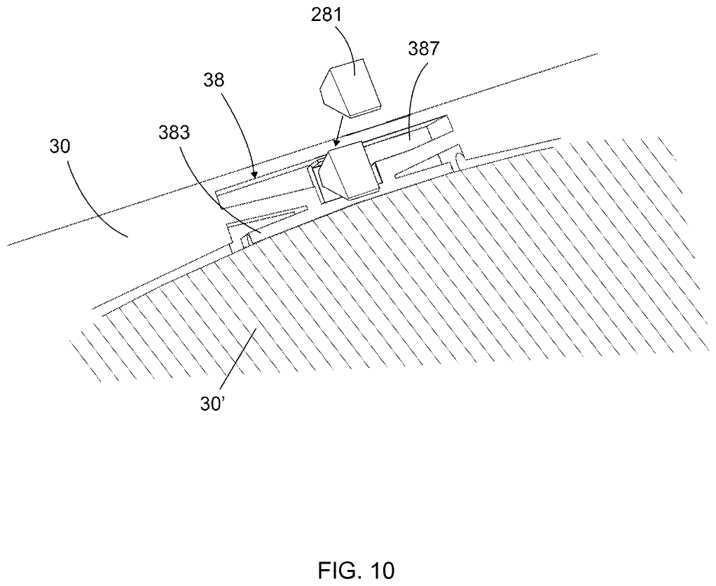

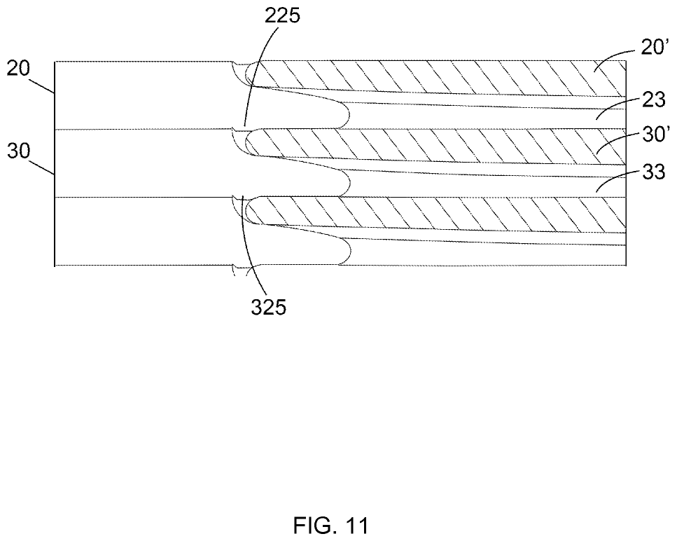

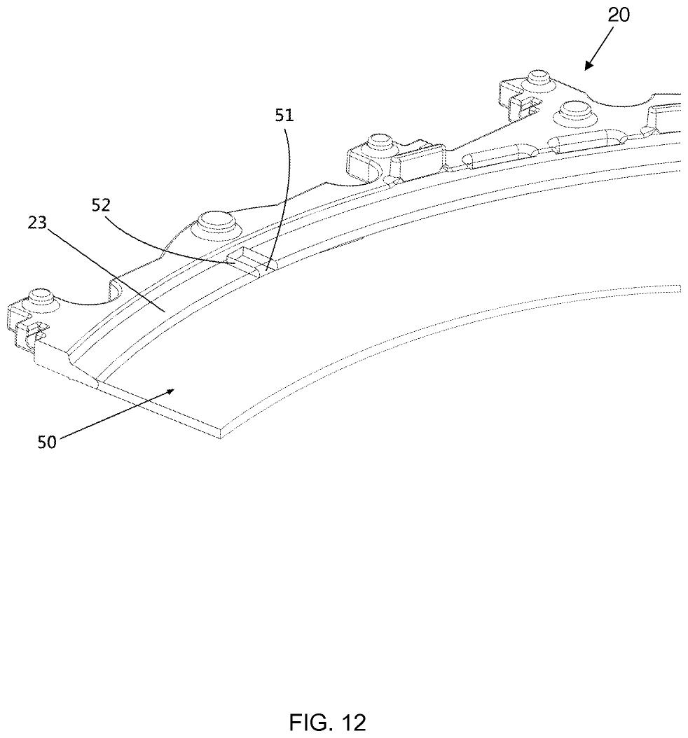

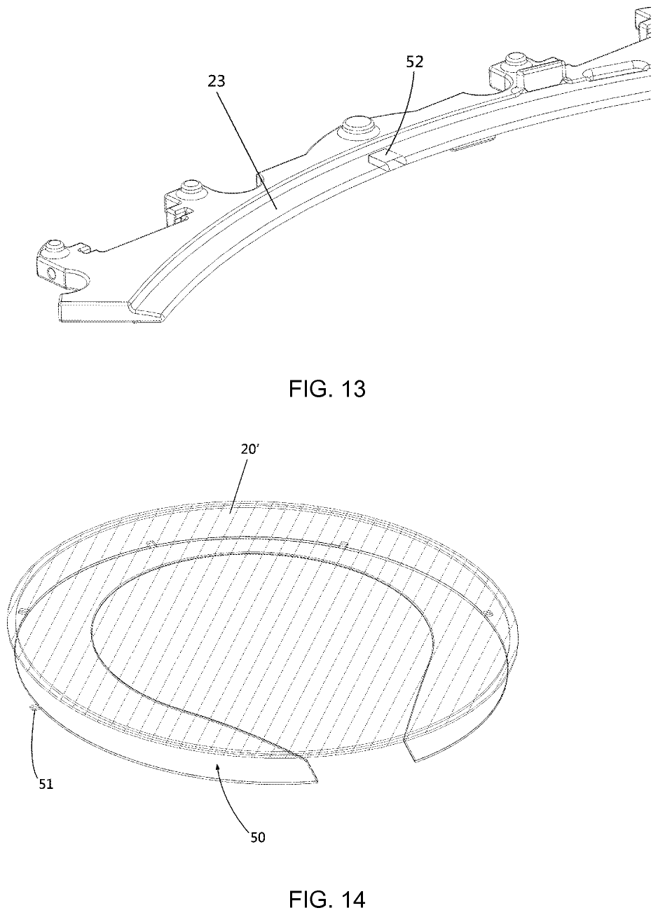

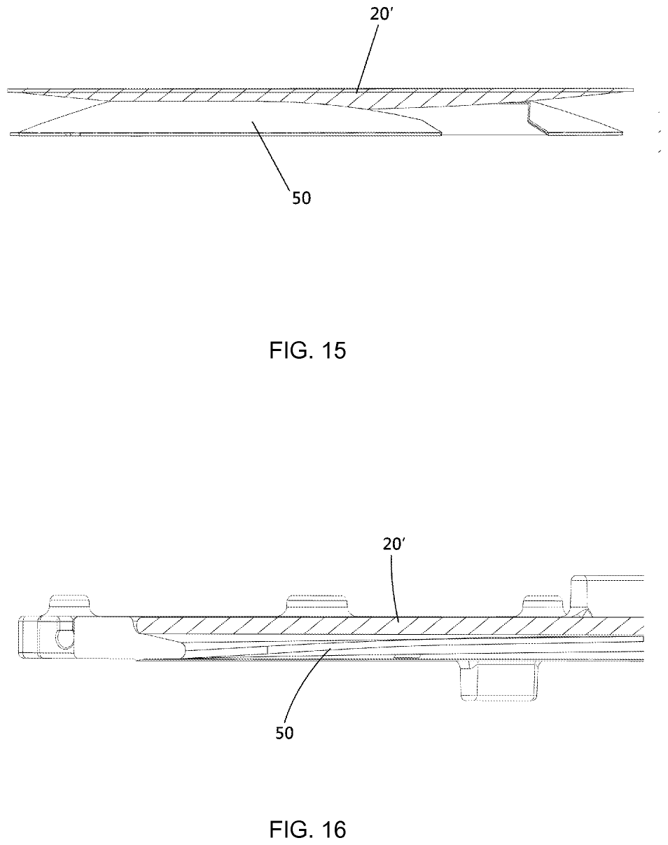

Referring to FIGS. 12 and 13, the first containing plate 20 comprises a bracing element 50 and a first carrying portion 23, wherein the first carrying portion 23 has at least one insertion hole 52, the bracing element 50 has a plug-in 51 at a position corresponding to the insertion hole 52. Each insertion hole 52 can accommodate each plug-in 51, so that the first carrying portion 23 could engage the bracing element 50 to abut against the first substrate 20′. Further referring to FIG. 14-16, the cross section of the supporting element 50 is in an arc shape which towards the direction of the first substrate 20′, so that when the first substrate 20′ is placed on the first carrying portion 23, a part of the bracing element 50 can abut against the back of the first substrate 20′ to counteract or slow down the deformation and depression of the first substrate 20′ due to the influence of gravity.

According to the concept of present invention, the structure of the adjustable carrying device 10 can be modified. Referring to FIG. 5, the first accommodating hole 27 may not pass through both the first top surface 21 and the first bottom surface 22, but may be a groove for the second upper positioning member 35 or the second lower positioning member 36 to partially extend into, and the second accommodating hole 37 can also be changed similarly. In addition, the first accommodating hole 27 and the second accommodating hole 37 can be omitted. In this case, the first upper positioning member 25, the first lower positioning member 26, the second upper positioning member 35, or the second lower positioning member 36 could be a device such as a spring, while these containing plates 20, 30 are in the compression state, the above-mentioned positioning members 25, 26, 35, 36 could abut against the top surface or bottom surface of each of the containing plates 20, 30. While these containing plates 20, 30 are in the extension state, the above-mentioned positioning members 25, 26, 35, 36 are no longer compressed and could be used as an abutment for positioning of the substrates. In addition, the structural shape and combination method of each of the protruding member 29 and the first fastening member 29′ could be changed according to the needs. Similarly, the structural shape and combination mode of each of the protruding member 39 and each of the second fastening member 39′ can be changed according to the needs, even these protruding members 29, 39 and these fastening members 29′, 39′ can be omitted. In addition, the design concepts of the insertion hole 52 of the first carrying portion 23 and the plug-in 51 of the bracing element 50 can also be replaced, such that the bracing element 50 provides an insertion hole, and the first carrying portion 23 has a plug-in.

Although the disclosure has been described in detail with reference to the foregoing embodiments, a person of ordinary skill in the art should understand that modifications may still be made to the technical solutions in the foregoing embodiments, or equivalent replacements may be made to part or all of the technical features; and these modifications or replacements will not cause the essence of corresponding technical solutions to depart from the scope of the technical solutions in the embodiments of the disclosure.

1. An adjustable carrying device for carrying a plurality of substrates, comprising:
at least two first containing plates respectively carrying a first substrate, each of the first containing plates comprising a first top surface, a first bottom surface, at least one first upper positioning member protruding upward from the first top surface, and at least one first lower positioning member protruding downward from the first bottom surface;
at least two second containing plates respectively carrying a second substrate and being arranged interval with the first containing plates, each of the second containing plates comprising a second top surface, a second bottom surface, at least one second upper positioning member protruding upward from the second top surface, and at least one second lower positioning member protruding downward from the second bottom surface; and
a plurality of stretchable elements being arranged on the first containing plate and the second containing plate, wherein the plurality of stretchable elements being capable of increasing the distance between the first containing plate and the second containing plate to form an extension state, or decreasing the distance to form a compression state.

2. The adjustable carrying device according to claim 1, the first containing plate further comprising a first accommodating hole, the second containing plate further comprising a second accommodating hole, wherein when the first containing plate and the second containing plate are in a compression state, each of the first lower positioning members extends into the second accommodating holes located below the corresponding position, each of the first upper positioning members extends into the second accommodating hole located above the corresponding position, each of the seconds upper positioning members extends into the first accommodating holes located above the corresponding position, and each of the second lower positioning members extends into the first accommodating hole located below the corresponding position.

3. The adjustable carrying device according to claim 1, wherein each of the first lower positioning members and each of the second upper positioning members are not overlapped in the vertical direction, and each of the first upper positioning members and each of the second lower positioning members are not overlapped in the vertical direction.

4. The adjustable carrying device according to claim 1, wherein when the first containing plate and the second containing plate are in an extension state, the horizontal position of the bottom edge of each of the first lower positioning members is lower than the horizontal position of the top edge of each of the second upper positioning members.

5. The adjustable carrying device according to claim 1, wherein when the first containing plate and the second containing plate are in an extension state, the horizontal position of the top edge of each of the first upper positioning members is higher than the horizontal position of the bottom edge of each of the second lower positioning members.

6. The adjustable carrying device according to claim 2, wherein each of the first accommodating holes passes through both the first top surface and the first bottom surface, and each of the second accommodating holes passes through both the second top surface and the second bottom surface.

7. The adjustable carrying device according to claim 2, wherein the first accommodating hole is recessed in the first upper positioning member or first lower positioning member, and the second accommodating hole is recessed in the second upper positioning member or second lower positioning member.

8. An adjustable carrying device for carrying a plurality of substrates, comprising:
at least two first containing plates respectively carrying a first substrate, each of the first containing plates comprises a first top surface, a first bottom surface, and a first holding element for resisting a second substrate carried by a second containing plate, wherein the first holding element comprises a first holding side wall, a first embedding opening, and a first bump;
at least two second containing plates respectively carrying a second substrate and being arranged interval with the first containing plates, each of the second containing plates comprises a second top surface, a second bottom surface, and a second holding element for resisting a first substrate carried by another adjacent first containing plate, wherein the second holding element comprises a second holding side wall, a second embedding opening, and a second bump; and
a plurality of stretchable elements for connecting the first containing plate and the second containing plate, and being retractable to change the distance between the containing plates;
wherein when the plurality of the stretchable elements shrink to reduce the distance between the containing plates, and the first bump of the first resisting element being embedded in the second embedding opening, the second holding side wall is pushed toward the second substrate, and the first resisting element resists against the second substrate through the second holding side wall.

9. The adjustable carrying device according to claim 8, the first bump further comprising a first bump top surface, a first bump bottom surface, and a first bump side surface located between the first bump top surface and the first bump bottom surface.

10. The adjustable carrying device according to claim 9, wherein the first bump side surface is bevelled surface, or an arc surface.

11. The adjustable carrying device according to claim 9, wherein the width of the first bump top surface is smaller than the width of the second embedding opening, and the width of the first bump bottom surface is greater than the width of the second embedding opening.

12. The adjustable carrying device according to claim 8, the first holding element further comprises a first fixed side wall, at least one connecting portion, and a first holding opening, wherein the first bump is connected to the first fixed side wall, the at least one connecting portion is connected between both sides of the first holding side wall and the first containing plate, and wherein the at least one connecting portion defines a first embedding opening with the first fixed side wall, and the first holding side wall defines the first holding opening with the first containing plate.

13. The adjustable carrying device according to claim 12, wherein the first bump is located at the central portion of the first fixed side wall and the first holding side wall.

14. The adjustable carrying device according to claim 12, the at least on connecting portion is substantially parallel to the first fixed side wall and the first holding side wall.

15. The adjustable carrying device according to claim 12, wherein the first holding side wall comprises an arc-shaped concave surface for resisting the first substrate.

16. The adjustable carrying device according to claim 8, the first containing plate further comprises a first carrying portion adjacent to the first top surface for carrying the first substrate, and wherein the first holding element is arranged on the first top surface.

17. The adjustable carrying device according to claim 16, wherein the first containing plate is made by one-piece injection molding process.

18. The adjustable carrying device according to claim 16, the first bottom surface further comprises a locating member, when the plurality of the stretchable elements shrink to reduce the distance between the containing plates, the locating member abuts against the second substrate carried by the second containing plate, and locates the second substrate on the central portion of the second containing plate.

19. An adjustable carrying device for carrying a plurality of substrates, comprising:
at least two containing plates respectively carrying a substrate, each of the containing plates comprises a first carrying portion for carrying the substrate, and a bracing element, wherein when the first substrate is placed on the containing plate, a part of the bracing element abut against the bottom surface of the first substrate; and
a plurality of stretchable elements being arranged on the containing plates;
wherein the plurality of stretchable elements being capable of increasing the distance between the containing plate to form an extension state, or decreasing the distance to form a compression state.

20. The adjustable carrying device according to claim 19, wherein the bracing element comprises at least one plug-in, the first carrying portion comprises at least one insertion hole at a position corresponding to the plug-in and accommodates each plug-in for engaging the bracing element.

21. The adjustable carrying device according to claim 19, wherein the bracing element comprises at least one insertion hole, the first carrying portion comprises at least one plug-in at a position corresponding to the insertion hole and extends to each insertion hole for engaging the bracing element.

22. An adjustable carrying device for carrying a plurality of substrates, comprising:
at least two containing plates respectively carrying a substrate; and
a plurality of stretchable elements being arranged on the containing plates, wherein the plurality of stretchable elements being capable of increasing the distance between the containing plate to form an extension state, or decreasing the distance to form a compression state;
wherein each of the containing plates comprises at least one protruding member, when the containing plates are in a compression state, the protruding member and the other protruding member on the adjacent containing plate to be joined together.

23. The adjustable carrying device according to claim 22, wherein the protruding member being made into a cover shape, when the containing plates are in a compression state, the protruding member cover on another protruding member on the adjacent containing plate.

24. An adjustable carrying device for carrying a plurality of substrates, comprising:
at least one first containing plate respectively carrying a first substrate;
at least one second containing plates respectively carrying a second substrate and being arranged interval with the first containing plates; and
a plurality of stretchable elements being arranged on the first containing plate and the second containing plate, wherein the plurality of stretchable elements being capable of increasing the distance between the first containing plate and the second containing plate to form an extension state, or decreasing the distance to form a compression state;
wherein each of the first containing plates further comprises at least one first fasten member, each of the second containing plates further comprises at least one second fasten member, when the containing plates are in a compression state, the first fasten member and the second fasten member are mutually connected.

25. The adjustable carrying device according to claim 24, wherein the first fasten member is made into a block shape, the second fasten member is made into a groove shape, when the containing plates are in a compression state, the first fasten members being inserted into the second fasten member.

26. The adjustable carrying device of claim 1, wherein the substrate is semiconductor wafer or display substrate.
